(19) United States
(12) Patent Application Publication
(10) Pub. No.: US 2003/0123279 A1
(43) Pub. Date: Jul. 3, 2003

(54) Silicon-on-insulator SRAM cells with increased stability and yield

(75) Inventors: Anthony Gus Aipperspach, Austin, TX (US); Todd Alan Christensen, Rochester, MN (US)

Correspondence Address: Robert R. Williams, IBM Corporation, Dept. 917, 3605 Highway 52 North, Rochester, MN, 55901-7829, US

(73) Assignee: International Business Machines Corporation, Armonk, NY

(21) Appl. No.: 10/036,712

(22) Filed: Jan. 3, 2002

(51) Int. Cl. G11C 11/00

(52) U.S. Cl. 365/154

(57) ABSTRACT

An SRAM memory cell made with increased stability using SOI technology is provided. Increased stability results from a decreased threshold voltage of the pullup pfets included in the inverter. Preferably the decrease of threshold voltage is achieved using a decreased concentration of phosphorus, antimony, arsenic, or other n-type ions during implantation.

### RELATED APPLICATION

This application is related to U.S. patent application Ser. No. 09/962,403 filed Sep. 25, 2001 entitled SILICON-ON-INSULATOR SRAM CELLS WITH INCREASED STABILITY AND YIELD, which application is owned by the assignee herein and which is incorporated by reference in its entirety.

### FIELD OF THE INVENTION

The present invention relates generally to the field of static random access memory (SRAM) cells and more specifically relates to increasing the stability of semiconductor-on-insulator, especially silicon-on-insulator (SOI), SRAM cells because certain transistors in the cells have a decreased threshold voltage.

### BACKGROUND OF THE INVENTION

Metal Oxide Semiconductor Field Effect Transistor (MOSFET) scaling on bulk silicon has been the primary focus of the semiconductor and microelectronic industry for achieving Complementary Metal Oxide Semiconductor (CMOS) chip performance and density objectives. The shrinking of MOSFET dimensions for high density, low power and enhanced performance requires reduced power supply voltages. Because power consumption is a function of capacitance, voltage, and transition frequency, the focus has been on reducing both the capacitance and the voltage as the operating or switching frequency increases. As a result, dielectric thickness and channel length of the transistors are scaled with power supply voltage. Power supply reduction continues to be the trend for future low voltage CMOS; however, transistor performance is severely impacted by both junction capacitance and the MOSFET body effect at these lower voltages. As technologies scale below 0.25 μm channel lengths to 0.15 μm and 0.1 μm and shorter, short channel effects, gate resistance, channel profiling and other barriers become an issue for advanced CMOS technologies. While significant success has been achieved with successive scaling of bulk CMOS technology, the manufacturing control issues and power consumption become increasingly difficult.

Silicon-on-insulator (SOI) technology is an enhanced silicon technology in which an insulating layer is situated above the bulk CMOS layer. SOI transistors are built in a thin layer of silicon on top of this buried insulator, typically silicon oxide, with bulk silicon below the buried insulator. Using SOI technology eliminates many of the concerns and obstacles of bulk silicon CMOS at low power supply voltages. SOI has significant advantages over bulk CMOS technology and achieves the scaling objectives of low power and high switching frequency. Naming only some of the technology benefits offered by SOI: SOI provides low power consumption, low leakage current, low capacitance diode structures, good sub-threshold current/voltage (IV) characteristics, a low soft error rate from both alpha particles and cosmic rays, and good SRAM access times. Because of these characteristics, SOI technology is especially useful in portable and wireless applications.

Standard advanced semiconductor technologies map into SOI technology without significant modifications. SOI process techniques include epitaxial lateral overgrowth, lateral solid-phase epitaxy and full isolation by porous oxidized silicon.

SOI networks can be constructed using the semiconductor process of techniques of separation by implanted oxygen and wafer-bonding and etch-back because they achieve low defect density, thin film control, good minority carrier lifetimes and good channel mobility characteristics. Structural features are defined by shallow trench isolation. Shallow trench isolation eliminates planarity concerns and multidimensional oxidation effects, thereby allowing technology migration and scaling to sub-0.25 μm technologies.

FIG. 1 illustrates a cross section through the length of a traditional SOI transistor 100. The SOI transistor 100 has a polysilicon gate 110 over a thin silicon dioxide layer 112. Source (drain) 114 and a drain (source) 116 are built over a buried insulative oxide 130 which is on top of a bulk silicon substrate 140. Between the source (drain) 114 and the drain (source) 116 and above the buried insulative oxide 130 is the floating body 120. On the outer sides of the source (drain) 114 and the drain (source) 116 are isolation oxides 118 to prevent a transistor from being electrically connected to another transistor. The buried insulative oxide layer 130 reduces the diffusion parasitic capacitance and the resulting floating body lowers the threshold voltage of the transistor, which, in turn, increases the performance of the SOI transistors. The voltage of the floating body 120, however, varies over time as it eventually leaks to Vdd or to some ground voltage which in turn causes the threshold voltage of the transistor 100 to vary. The floating body effects were at first considered beneficial because of the increased speed at which a transistor can switch but performance could not be predicted using transistors in which the bodies were allowed to float. Floating body transistors, moreover, are extremely sensitive to noise and to nonperfect input voltage on the gates. Because of this sensitivity and hysteresis, i.e., “history effects” meaning that the voltage on the floating body is dependent upon previous cycles and the time durations of the cyclic input, floating body transistors are difficult to match. For instance, a high signal immediately after two or three other high signals might be too fast to synchronize with other signals. Similarly, a low signal immediately after two or three high signals might be too slow.

These floating body effects are especially noticeable in SRAM cells which require the transistors to hold their values and to be reproducibly responsive to the same voltages during high frequency clocking cycles. FIG. 2a is a traditional SRAM cell 200 in which the feedback from the output of one inverter is the input to the other inverter, i.e., cross-coupled inverters; this arrangement stabilizes the state of the SRAM. An inverter comprises a n-type field effect transistor (nfet) 250 (270) having an input and output connected to the gate and drain of a p-type field effect transistor (pfet) 240 (260). The gates of nfets 230 and 280 are connected to a word line 220 and pass the data into and out of the memory cell 200 and are hence referred to as pass devices or transfer devices. The sources of the pass nfets 230 and 280 are connected to the bit line complement 210 and true 290, respectively.

Cross-coupling of the two inverters is achieved by connecting the drains of nfet 270 and pfet 260 with the gates of pfet 240 and nfet 250 and, similarly, the drains of nfet 250 and pfet 240 are connected to the gates of pfet 260 and nfet 270. There is a symmetry to the cell in that pfets 240 and 260 are matched, as are nfets 230 and 280; and nfet 250 is matched with nfet 270. Pfets are good at passing a higher voltage level, i.e., a value of “1”, whereas nfets are good at passing lower voltage levels such as a value of “0.” To store a value of 01 in the memory cell 200, nfet 250 and pfet 260 would both be turned on; whereas to store a value of 10 in the memory cell nfet 270 and pfet 240 would both be turned on. By convention, it is the value of the “true” side which is the stored value.

Small mismatches in the devices during processing can cause the cell to favor one of the states, either a “1” or a “0.” Mismatches result from dislocations between the drain and floating body and between the floating body and the source or from metal precipitates forming during the actual growth and processing of the transistors. These dislocations may locally increase voltage leakage of the floating body to/from the source or drain thus, depending upon the location of the defect, lowering or raising the potential of the floating body. Switching history and its effect on the SOI floating bodies of the transistor, moreover, also contribute to differences in voltages of devices designed to be symmetric. In a memory cell, when a word line is on, a value of 0 is really between Vdd and ground, and a value of 1 is not actually at Vdd but somewhere between Vdd and ground. Anytime a word line is on and the bit line is held or precharged to Vdd, such as during a half-select or read operation, the zero voltages may increase to the point that the cell can inadvertently flip state resulting in stability failure.

FIG. 2b shows the history and floating body effects within the memory cell of FIG. 2a. The bottom nfet 250 can be weaker relative to the average or starting condition than it was designed to be while the pass nfet 230 becomes stronger.

The labeling of “strong” and “weak” qualitatively refers to the floating body effects which degrades the stability of the cell because of past switching history. It is known that pfets may exhibit floating body effects to a lesser degree than nfets. To accommodate these effects, the sizes of the transistors may be changed so that a weak transistor may be designed to be larger and a strong transistor made be designed to be smaller. Thus, nfet 250 and pfet 260 may be designed to be larger and stronger, and transfer nfet 230 and pfet 240 may be intentionally designed to be smaller and weaker. In fact, improving the stability of SRAM cells has been traditionally accomplished by changing the transistor device width/length ratios. Many of the transistors, however, are already at or near their minimum dimensions for the technology and making the transistors smaller is not feasible.

There still is a need in the industry, however, to compensate for floating body effects which cause memory cell stability failures without changing the sizes and hence, the designs, of individual transistors.

### SUMMARY OF THE INVENTION

A principal object of the present invention is to provide a SRAM memory cell with increased stability and yield. This invention is achieved in a SRAM memory cell, comprising two inverters in a symmetric and complementary arrangement, each of the inverters having a pullup pfet with a decreased threshold voltage. The memory cell may have one transfer nfet connected to each inverter, the transfer nfets having an increased threshold voltage. A pulldown nfet of each inverter within the memory cell may also have an increased threshold voltage. The memory cell may be made from bulk silicon, or from a semiconductor-on-insulator technology.

The semiconductor-on insulator technology may be a silicon-on-insulator technology and the insulator may be silicon dioxide. Alternatively, the insulator may be sapphire. The lower threshold voltage may be achieved during manufacture decreasing the concentration of phosphorus, arsenic, antimony, or other n-type ion implantation prior to definition of a gate of the pullup pfets. Alternatively, the lower threshold voltage may be achieved with an decreased thickness of a gate oxide layer above a floating body of the pullup pfet(s).

It is further contemplated that the semiconductor-on-insulator technology may include from semiconductors of Group III, V and/or from Group II, VI of the periodic chart.

The invention may also be considered a SRAM memory cell having increased stability, comprising: a word line; a true bit line; a complement bit line; a first transfer nfet connected to the word line; a first inverter comprising a first pfet and a first nfet whose gates and drains are connected; a second transfer nfet whose gate is connected to the word line; and a second inverter comprising a second pfet and a second nfet whose gates and drains are connected; wherein the first and second inverter are cross-coupled to the output of the second and first transfer nfets, respectively and the first and second pfets have a decreased threshold voltage. The first and second pullup pfets devices may be silicon-on-insulator (SOI) transistors whose threshold voltage was decreased using a smaller concentration of phosphorus, antimony, or arsenic ions during implantation; or after manufacture the threshold voltage of the pfets may be adjusted with an appropriate p-type dopant, such as boron. Alternatively, the threshold voltage of the first and second pullup pfet devices may be decreased with an decreased thickness of a gate oxide layer above a floating body. Additionally, the first and second transfer nfets and/or the nfet of the first inverter and the second nfet of the second inverter may also have increased threshold voltages above the threshold voltages of other remaining nfets in the SRAM memory cell.

The invention may also be considered a semiconductor memory cell for use in memory arrays, comprising a means to receive a word line signal; a means to receive a true bit line signal; a means to receive a complement bit line signal; a means to cross-couple a first inverter connected to the means to receive the true bit line signal with a second inverter connected to the means to receive a complement bit line signal; and a means to increase the stability of the inverters. The means to receive a word line signal may comprise two transfer nfets, each of which are connected to a word line; the output of first transfer nfet connected to the input of the second inverter and the output of the second transfer nfet connected to the input of the first inverter; and the means to increase the stability of the inverter comprising a decreased threshold voltage of the two pullup pfets. There may also be means to increase the threshold voltage of the first and second transfer nfets and/or a first and second pulldown nfet, the first pulldown nfet included in the first inverter and the second pulldown nfet included in the second inverter. The means to decrease the threshold voltage of the pullup pfets may comprise a decrease concentration of phosphorus, antimony, arsenic, or other n-type ions implanted into a region below a gate of each pfet and between a source and a drain of each pfet prior to gate definition.

### BRIEF DESCRIPTION OF THE DRAWINGS

The present invention together with the above and other objects and advantages may best be understood from the following detailed description of the preferred embodiments of the invention illustrated in the drawings, wherein:

FIG. 1 illustrates a conventional SOI transistor;

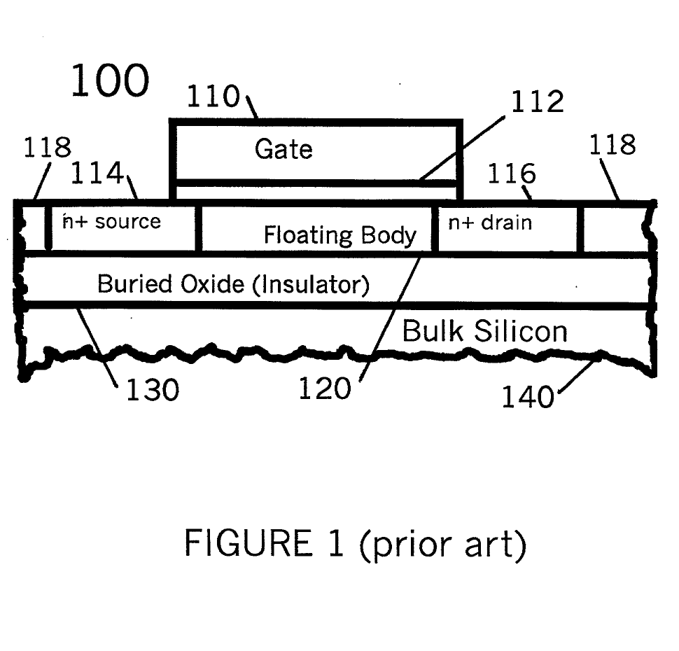

FIG. 2a is a circuit diagram of a SRAM cell;

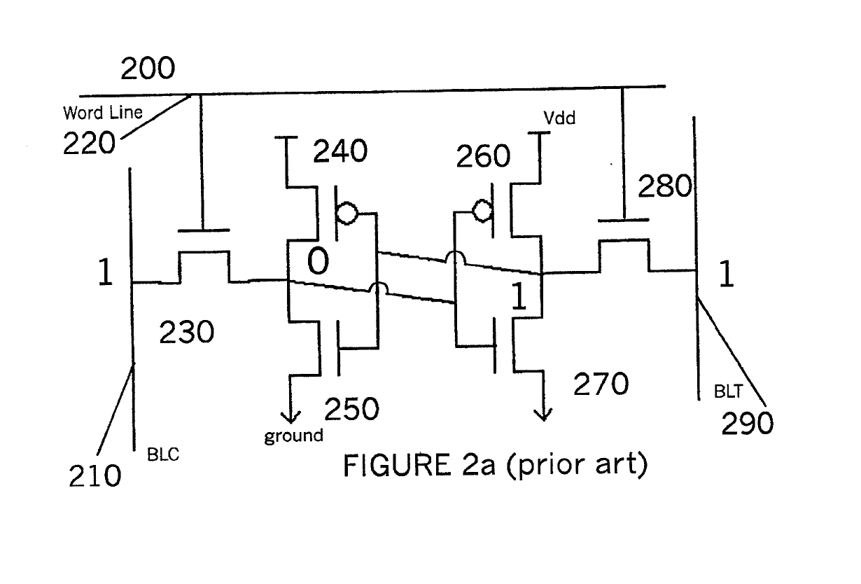

FIG. 2b is the circuit diagram of FIG. 2a showing the strength or weaknesses of the floating body effects.

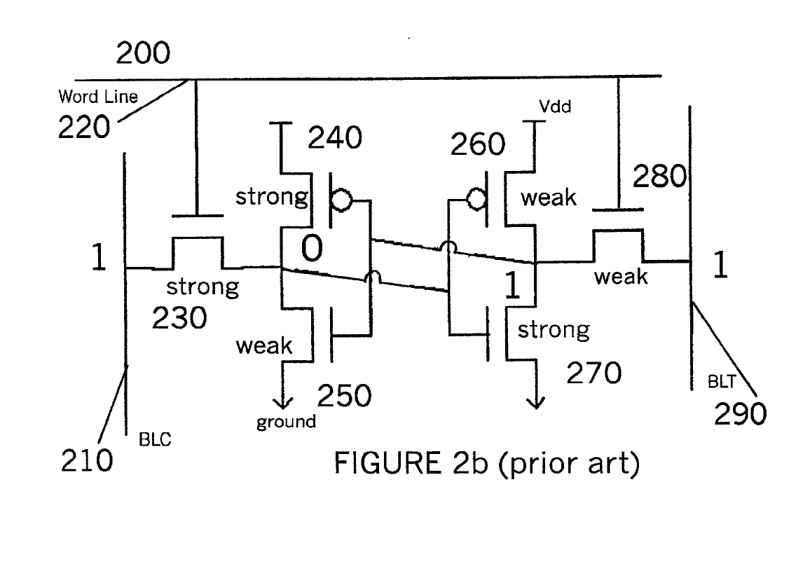

FIG. 3 is a mask diagram of a SRAM cell in accordance with a preferred embodiment of the invention. It is suggested that FIG. 3 be printed on the face of the patent.

### DETAILED DESCRIPTION OF THE PREFERRED EMBODIMENTS

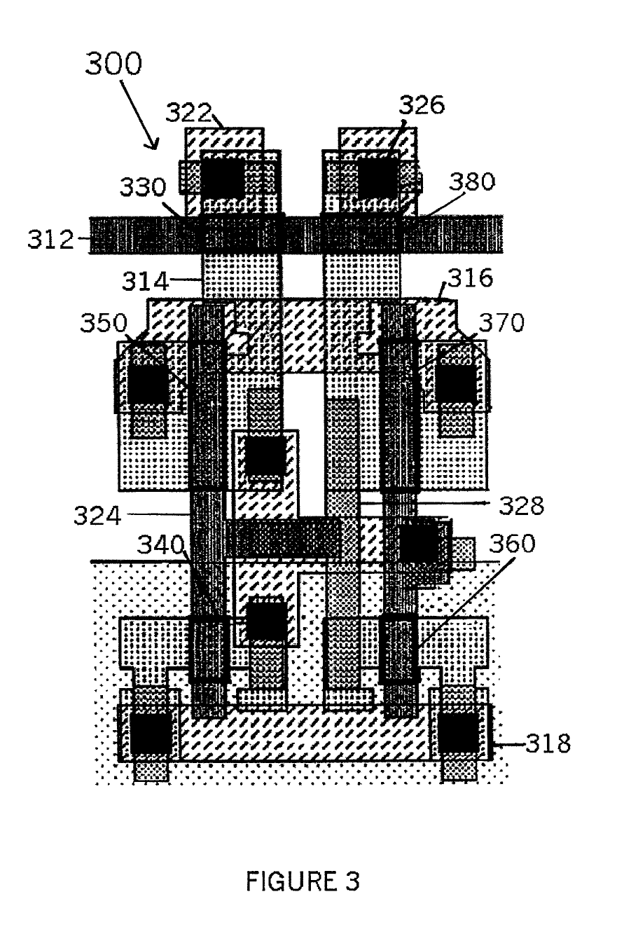

Having reference now to the Drawing, in FIG. 3 therein is shown a SRAM memory cell in accordance with an embodiment of the invention. In the preferred embodiment, those pfets susceptible to floating body effects have a decreased threshold voltage. FIG. 3 shows the six transistors embodied in an SRAM cell. The two transfer nfets 330 and 380 are shown with the gate 312, and a diffusion area 314 as a source/drain. The two pulldown nfets 350 and 370 are connected to ground 316, and the two pullup pfets 340 and 360 are shown connected to Vdd 318. Area 322 is a first metal layer; darker area 324 is a polysilicon area, contacts 326 are shown as the black areas; and a local interconnect 328 behaves as a metal layer connection between the polysilicon areas 324 or diffusion areas 314 to the first metal layer 322.

In an embodiment of the invention, the threshold voltages of pfets 340, 360 are decreased by a reduced concentration of an n-type ion being implanted into the pfets. While it has generally been known that threshold voltages of transistors can be adjusted with varying dopant concentrations, this invention focuses particularly on discovering that the threshold voltages of the various transistors in an SRAM cell impacts the stability of the cell, especially in SOI technology.

In the related U.S. patent application Ser. No. 09/962,403 filed Sep. 25, 2001 entitled SILICON-ON-INSULATOR SRAM CELLS WITH INCREASED STABILITY AND YIELD, referenced and incorporated at the beginning, increasing the threshold voltages of the transfer nfets 330, 380 was found to have stabilized the SRAM cells to some degree. Increasing the threshold voltages of nfets, however, may adversely impact the performance of the memory cell because a larger voltage drop is required for proper operation. Decreasing the threshold voltages, however, causes more leakage current in the SRAM cells resulting in cumulative power consumption that may be greater than the voltage required to change states of the SRAM cells, especially when there are millions of SRAM cells. Thus, these two factors as embodied in the ratio of the transfer nfets to the pulldown nfets which determines the maximum “down” level must be lower than the switch point of the cell which is determined by the ratio of the pullup pfets to the pulldown nfets. Thus, two ratios must be considered when adjusting threshold voltages and achieving the desired stability of the cells.

Under certain circumstances, leakage current may not be a problem and in these cases, it may be preferable to merely decrease the threshold voltages of the pullup pfets 340, 360. In circumstances where leakage current must be minimized, it may be desired to decrease the threshold voltage of the pullup pfets in conjunction with increasing the threshold voltage of the transfer nfets 330 and 380. Under some circumstances, it may be necessary to only increase the threshold voltage of the transfer nfets 330 and 380, except where the desired stability is not achieved. The redesign of the SRAM cell may not be economical or feasible, so a technique to lower the threshold voltage of the pfets may be used to achieve the proper result. This decrease of threshold voltage of the pfets and/or the increase of threshold voltage of the nfets improves the pfet to nfet ratio and furthermore, allows more flexibility to improve the pfet to nfet ratio.

Because of the proximity of the nfets and ease of processing, it is important that the implantation or other technique to decrease the threshold voltages of the pullup pfets not affect the other transistors in the memory cell and proximity. The notion of decreasing lowering the threshold voltage of the pfets in the context of this invention may involve a comparison of the threshold voltage of the pullup pfets with other pfets on the chip, and the threshold voltage of the pullup pfets is less than the threshold voltage of those other pfets. Alternatively, the invention may involve a comparison of the threshold voltage of the pullup pfets with SRAM pullup pfets that have a higher concentration of the n-type dopants. Typically, SRAM pullup pfets are doped with a concentration of n-type dopants so that they can be turned off; but this invention takes advantage of the discovery that the threshold voltage of the pullup pfets can be even lowered to achieve greater stability, especially in SOI technology. It is further known that selectively decreasing the gate oxide thickness of the pfets will also decrease the threshold voltages, but ion implantation is preferred because changing gate oxide thicknesses increases process complexity and is more difficult to manufacture.

While the preferred embodiment is presented as using a smaller concentration of phosphorus, arsenic, antimony or other n-type ion for implantation into SOI pullup pfets, it is to be understood that the stability of memory cells using any semiconductor technology on any insulator can be enhanced by decreasing the threshold voltage of the pullup devices. Thus, the inventive concepts herein apply also to sapphire-on-silicon technology. Moreover, one of skill in the art will appreciate that the techniques to decrease the threshold voltage and improve the stability of the memory cell can be implemented in indium phosphide, gallium arsenide, germanium, and other Group III, V and Group II, VI semiconductor technologies. Improving the stability of a SRAM cell by modifying the threshold voltages of the fets by ion implantation is not limited to semiconductor-on-insulator devices only, but also is applicable to transistors manufactured using bulk silicon technology.

Modifying the threshold voltage characteristics of a transistor has been well understood and it is known in the art how to adjust the threshold voltage with ion implantation. For threshold voltage control, the dose is typically in the order 10¹² atoms per square centimeter and the projected range is typically less than a micron below the silicon surface. It has been discovered, however, that SRAM cell stability is dependent upon the threshold voltages characteristics of the transistors, and to decrease the threshold voltage of the pullup pfets by 20-100 millivolts may be sufficient. Lowering the threshold voltage of the pullup pfets can be achieved by decreasing the dopant concentration by a small percentage while still maintaining approximately the same order of magnitude. Alternatively, the pfets may be prepared as in normal processing and tested, if the cell does not exhibit the desired stability because the threshold voltage of the pfets is too high, future pfets may then be processed by an additional doping of a p-type ion, such as boron, into the pfets which decreases the threshold voltage.

The implantation preferably occurs prior to gate definition. As an example of how to process the pfets, typically a mask may be applied to the nfets and then the threshold voltage of the pfets would be lowered by a decreased concentration of an appropriate n-type dopant, such as antimony, arsenic, phosphorus. The photoresist mask may be removed and if further implantation of the nfets were to occur, a mask could then be applied to the adjusted pfets and then ion implantation of the nfets with boron or other appropriate ion would take place. After implantation, a short annealing treatment may be necessary to ensure that the implanted dopant atoms are located in substitutional sites where they act as donors or acceptors, and also to restore the crystal quality. Various materials such as photoresist, metal, or oxide may be used as a mask to prevent ions from entering selected regions of the wafer. If positive photoresist is used, it is applied to the entire wafer, then light impinges on the areas of the pfets whose threshold voltages are to be lowered. The wafer is then washed with a developing solution which dissolves the light-affected photoresist. The remaining photoresist blocks the implantation. Additional factors to consider and materials for ion implantation to adjust the threshold voltage of various semiconductors are set forth in, e.g., Trapp, Blanchard, Lopp, and Kamins, The Semiconductor Technology Handbook, Technology Associates 1985 pp. 7.1, 7.1, and 12.1; and El-Kareh and Bombard, Introduction to VLSI Silicon Devices, Kluwer Academic Publishers 1986, pp. 464-473.

Thus, it has been discovered that lowering the threshold voltages of the pullup pfet devices in a SRAM cell decreases the cell's sensitivity to small defects, especially noticeable in SOI technology. This in turn greatly decreases the number of stability failures which in turn increases the yield. Lowering the threshold voltage can be best accomplished using a decreased concentration of an n-type ion implantation of the floating body above the buried oxide layer prior to gate, source, and drain definition. Thus, while the present invention has been described with reference to the details of the embodiments of the invention shown in the drawing, these details are not intended to limit the scope of the invention as claimed in the appended claims.

What is claimed is:

1. A SRAM memory cell, comprising two inverters in a symmetric and complementary arrangement, each of the inverters having a pullup pfet with a decreased threshold voltage.

2. The SRAM memory cell of claim 1, further comprising a transfer nfet connected to each of the inverters, the transfer nfets having an increased threshold voltage.

3. The SRAM memory cell of claim 2, further comprising a pulldown nfet in each of the inverters, the gates of the pullup pfets and the gates of the pulldown nfets connected, the pulldown nfets having an increased threshold voltage.

4. The SRAM memory cell of claim 1, wherein the memory cell is made from bulk silicon.

5. The SRAM memory cell of claim 1, wherein the memory cell is made from semiconductor-on-insulator technology.

6. The SRAM memory cell of claim 5, wherein the semiconductor-on insulator technology is silicon-on-insulator technology and the insulator is silicon dioxide.

7. The SRAM memory cell of claim 5, wherein the semiconductor-on-insulator technology is silicon-on-insulator technology and the insulator is sapphire.

8. The SRAM memory cell of claim 1, wherein the lower threshold voltage is achieved during manufacture by a decreased concentration of an n-type ion implantation prior to definition of a gate of the pullup pfets.

9. The SRAM memory cell of claim 1, wherein the lower threshold voltage is achieved by a decreased thickness of a gate oxide layer above a floating body of the pullup pfets.

10. The SRAM memory cell of claim 5, wherein the semiconductor-on-insulator technology is from semiconductors of Group III, V.

11. The SRAM memory cell of claim 5, wherein the semiconductor-on-insulator technology is from semiconductors of Group II, VI.

12. A SRAM memory cell having increased stability, comprising:
(a) a word line;
(b) a true bit line;
(c) a complement bit line;
(d) a first transfer nfet connected to the word line;
(e) a first inverter comprising a first pfet and a first nfet whose gates and drains are connected, the first pfet having a decreased threshold voltage;
(f) a second transfer nfet whose gate is connected to the word line; and
(g) a second inverter comprising a second pfet and a second nfet whose gates and drains are connected, the second pfet having a decreased threshold voltage;
wherein the first and second inverter are cross-coupled to the output of the second and first transfer nfets, respectively.

13. The SRAM memory cell of claim 12, wherein the first and second pull up pfet devices are silicon-on-insulator (SOI) transistors whose threshold voltage was decreased using a reduced concentration of antimony, arsenic, or phosphorus ion during implantation.

14. The SRAM memory cell of claim 12, wherein the first and second pfet devices are SOI transistors whose threshold voltage was decreased with an decreased thickness of a gate oxide layer above a floating body.

15. The SRAM memory cell of claim 12, wherein the first and second transfer nfets and/or the first nfet of the first inverter and the second nfet of the second inverter have increased threshold voltages above the threshold voltages of other remaining nfets in the SRAM memory cell.

16. A semiconductor memory cell for use in memory arrays, comprising:
(a) means to receive a word line signal;
(b) means to receive a true bit line signal;
(c) means to receive a complement bit line signal;
(d) means to cross-couple a first inverter connected to the means to receive the true bit line signal with a second inverter connected to the means to receive a complement bit line signal; and
(e) means to increase the stability of the first and second inverter.

17. The semiconductor memory cell of claim 15, wherein the means to receive a word line signal comprises two transfer nfets, each of which are connected to a word line, the output of first transfer nfet connected to the input of the second inverter and the output of the second transfer nfet connected to the input of the first inverter; and the means to increase the stability of the two inverters comprises decreasing the threshold voltage of both a first pullup pfet in the first inverter and a second pullup pfet in the second inverter.

18. The semiconductor memory cell of claim 17, further comprising means to increase the threshold voltage of two transfer nfets and/or two pulldown nfets, the first pulldown nfet included in the first inverter and the second pulldown nfet included in the second inverter; the gates of the first pullup pfet and the first pulldown nfet connected together in the first inverter and the gates of the second pullup pfet and the second pulldown nfet connected together in the second inverter.

19. The semiconductor memory cell of claim 17, wherein the means to decrease the threshold voltage of the two pullup pfets comprises implantation of a reduced concentration of phosphorus, antimony, or arsenic ions into a region below a gate of each pfet and between a source and a drain of each pfet prior to gate definition.

20. The semiconductor memory of claim 19, wherein the means to increase the threshold voltage of the two transfer nfets and the two pulldown nfets comprises implantation of boron ions into a region below a gate of each nfet and between a source and a drain of each nfet prior to gate definition.
